(19) United States
(12) Patent Application Publication
(10) Pub. No.: US 2025/0201643 A1
(43) Pub. Date: Jun. 19, 2025

(54) STACKED IC PACKAGE

(71) Applicant: Samsung Electronics Co., Ltd., Suwon-si (KR)

(72) Inventors: Sungeun JO, Suwon-si (KR); Byungwoo BANG, Suwon-si (KR)

(73) Assignee: Samsung Electronics Co., Ltd., Suwon-si (KR)

(21) Appl. No.: 18/920,340

(22) Filed: Oct. 18, 2024

(30) Foreign Application Priority Data
Dec. 19, 2023 (KR) 10-2023-0185597

(51) Int. Cl. H01L 23/24; H01L 23/00; H01L 23/367; H01L 25/18; H10B 80/00

(52) U.S. Cl. CPC H01L 23/24; H01L 23/3672; H01L 23/562; H01L 25/18; H01L 24/14; H01L 24/16; H01L 2224/14051; H01L 2224/16146; H01L 2224/16225; H01L 2225/06513; H01L 2225/06517; H01L 2225/06589; H01L 2924/1431; H01L 2924/14361; H10B 80/00

(57) ABSTRACT

A stacked integrated circuit (IC) package includes: a package substrate; a first die stacked on the package substrate; second dies each stacked on the first die and spaced apart from each other on the first die; and a stiffener stacked on the first die and arranged between the second dies.

### CROSS-REFERENCE TO RELATED APPLICATIONS

This application claims the benefit under 35 USC § 119(a) of Korean Patent Application No. 10-2023-0185597 filed on Dec. 19, 2023, in the Korean Intellectual Property Office, the entire disclosure of which is incorporated herein by reference for all purposes.

### BACKGROUND

### 1. Field

The following description relates to a stacked integrated circuit (IC) package.

### 2. Description of Related Art

As the use of portable electronic devices has increased and various electronic devices require high-performance continue to be developed, there have been proposals and attempts to develop various types of integrated circuit (IC) packages that integrate as many high-capacity memory chips as possible in a form factor with limited space. In other words, there are efforts to increase memory density. Particularly, there has been active research to develop a three-dimensional (3D) IC package in which memory chips are stacked in a vertical direction to improve the degree of integration.

An IC package may be formed by stacking a bottom die on a package substrate and a top die on the bottom die. For example, the IC package may be formed by stacking a logic die (for calculation and control) on the package substrate, and then stacking a memory die for data storage on the logic die. Such an IC package may form a processing-in-memory (PIM) memory semiconductor capable of calculation and data processing by stacking high bandwidth memories (HBMs) on the logic die. The PIM semiconductor memory may provide processing communication and calculation between memory and processors at a faster rate in a supercomputer or a high-performance computing (HPC) system, in particular when a bottleneck might be expected at moving data in and out of processing elements.

An HBM-based 3D IC package may have less HBM capacity than a 2.5-dimensional (2.5D) IC package. To overcome this, a technique for stacking multiple HBMs on one logic die may be employed. However, according to the nature of 3D stacking, physical coupling between the HBMs or between the HBMs and the logic die naturally involves thermal, which may increase temperature. In addition, stacking four or more HBMs in 3D to provide additional storage capacity may warp the logic die.

The above description has been possessed or acquired by the inventor(s) in the course of conceiving this disclosure and was not necessarily publicly known before the date of this disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a stacked integrated circuit (IC) package, includes: a package substrate; a first die stacked on the package substrate; second dies each stacked on the first die and spaced apart from each other on the first die; and a stiffener stacked on the first die and arranged between the second dies.

The second dies may include two neighboring second dies, and the stiffener may be formed lengthwise in a partition space between the two neighboring second dies.

The stiffener may be formed as one integral body.

The stiffener may be formed of stainless steel or aluminum.

The second dies may be memory dies and the first die may be a processor die.

The stiffener may include a linear structure arranged in a corresponding linear space between two second dies without contacting the two second dies.

The stiffener may include: a first linear portion disposed between two second dies; and a second linear portion having a first side and a second side opposite the first side, wherein the first side faces the two second dies and second side, and wherein the second linear portion faces outward from the stacked IC package.

The first linear portion and the second linear portion may be perpendicular to each other and may be connected to, or integrated with, each other to form the stiffener as one body.

The second dies may include four second dies and the four second dies may be arranged in a matrix pattern and spaced apart from each other.

The stiffener may include: a first linear portion arranged between the four second dies; and a second linear portion perpendicular to the first linear portion and arranged between the four second dies.

The first linear portion and the second linear portion may be connected to, or integrated with, each other to form the stiffener as one body.

The stiffener may further include a third linear portion parallel to the first linear portion and perpendicular to the second linear portion.

The first die may be wider in a dimension parallel to the first linear portion than in a dimension parallel to the second linear portion, and the first linear portion may be thicker than the second linear portion.

The stacked IC package may further include a thermal dissipation module disposed on the second dies and the stiffener.

The stacked IC package may further include: a thermal interface material (TIM) applied between the thermal module and at least one of the second dies or the stiffener.

In another general aspect, a stacked integrated circuit (IC) package includes: a package substrate; a logic die stacked on the package substrate; memory dies each stacked on the logic die and spaced apart from each other on the first die; and a stiffener stacked on the logic die and arranged between the memory dies.

Each of the memory dies may be formed with a high bandwidth memory (HBM) and each of the memory dies may have a respective electrical connection with the logic die.

The stiffener may have a linear shape and may be formed in a linear partition space between two neighboring memory dies.

The stiffener may be formed as one integral body.

The stiffener, from a perspective above the stacked IC package, may include a “+” shape or an “H”.

Other features and aspects will be apparent from the following detailed description, the drawings, and the claims.

### BRIEF DESCRIPTION OF THE DRAWINGS

FIG. 1 is a cross-sectional view of a stacked integrated circuit (IC) package, according to one or more example embodiments.

FIG. 2 is a plan (overhead) view of a stacked IC package according to one or more example embodiments.

FIG. 3 is a plan view of a stacked IC package, according to one or more example embodiments.

FIG. 4 is a plan view of a stacked IC package, according to one or more example embodiments.

FIG. 5 is a plan view of a stacked IC package, according to one or more example embodiments.

FIG. 6A is an overhead view showing warpage of a stacked IC package without a stiffener, according to one or more example embodiments.

FIG. 6B is an overhead view showing warpage of a stacked IC package with a stiffener, according to one or more example embodiments.

FIG. 7 is a cross-sectional view of a stacked IC package, according to one or more example embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

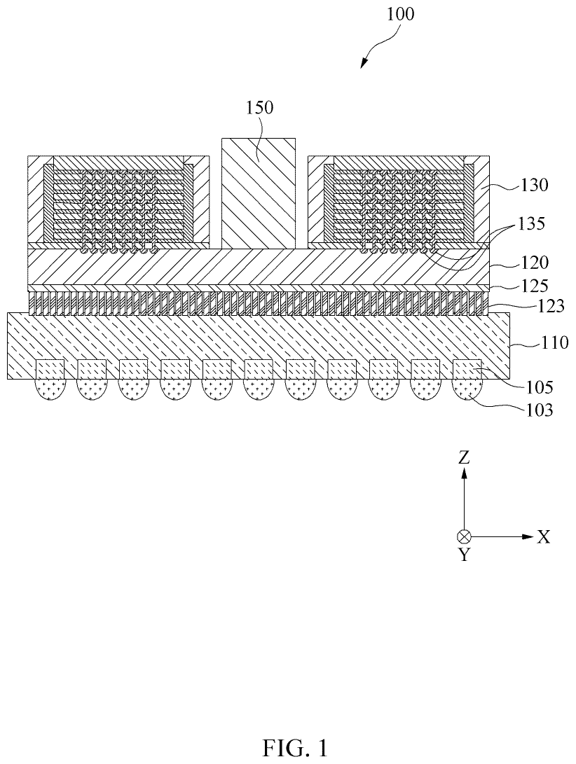

FIG. 1 is a cross-sectional view of a stacked integrated circuit (IC) package 100, according to one or more example embodiments.

Referring to FIG. 1, the stacked IC package 100 of an example embodiment may be formed by stacking dies (e.g., 120 and 130). For example, the stacked IC package 100 may include at least some of a package substrate 110, a first die 120, second dies 130, and a stiffener 150.

In an example embodiment, the package substrate 110 may form a base of the stacked IC package 100. The package substrate 110 may provide a physical mounting space and structural support for the components of the stacked IC package 100 to be mounted therein.

In an example embodiment, the dies 120 and 130 may be stacked on the package substrate 110. For example, the first die 120 and the second dies 130 may be stacked on one surface (e.g., a surface in a +Z direction or a top surface) of the package substrate 110.

In an example embodiment, a substrate connection portion 105 may be provided on another surface (e.g., a surface in a −Z direction or a bottom surface) of the package substrate 110. The substrate connection portion 105 may connect the stacked IC package 100 to an external substrate or an external electronic device (hereinafter referred to as an “external substrate,” but the stacked IC package 100 may be connected to other targets). A coupling member 103 may be applied onto the substrate connection portion 105. The coupling member 103 may be, for example, a shouldering member configured to mate with another surface or a conductive paste.

In an example embodiment, the package substrate 110 may transmit electrical signals from the dies 120 and 130 to the external substrate through the substrate connection portion 105. Alternatively, the package substrate 110 may transmit power from the external substrate to the plurality of dies 120 and 130 through the substrate connection portion 105.

In an example embodiment, the first die 120 may be stacked on the package substrate 110. For example, the first die 120 may be stacked on one surface (e.g., the top surface in the +Z direction) of the package substrate 110. The first die 120 may be either a logic die or a memory die. However, this is provided only as an example, and the type of the first die 120 is not limited thereto. In an example embodiment, the first die 120 may also be a processor die. The first die 120 may provide a space/surface for the second dies 130 and the stiffener 150 to be mounted therein.

In an example embodiment, the first die 120 may include a first connection portion 125. The first connection portion 125 may electrically connect the first die 120 and the package substrate 110. A connecting member 123 may be provided between the first connection portion 125 and the package substrate 110. The connecting member 123 may be, for example, a shouldering member, a cable, a conductive structure, or a conductive paste.

In an example embodiment, the first connection portion 125 may include a first power transfer region and/or a first signal transfer region. The first die 120 may receive power from the package substrate 110 through the first power transfer region. The first die 120 may transmit or receive a signal to or from the package substrate 110 through the first signal transfer region.

In an example embodiment, the second dies 130 may be stacked on the first die 120. For example, the second dies 130 may each be stacked on a top surface (e.g., a surface in the +Z direction) of the first die 120. The second dies 130 may be either logic dies or memory dies. For example, the first die 120 may be a logic die, and the second dies 130 may be memory dies. For example, the first die 120 may be a memory die, and the second dies 130 may be logic dies. For example, the first die 120 may be a logic die, and the second dies 130 may be logic dies. However, these are provided only as examples, and the types of the first die 120 and the second dies 130 are not limited thereto.

In an example embodiment, the second dies 130 may each include a second connection portion 135. The second connection portion 135 may electrically connect the second die 130 and the first die 120. As an example, the second connection portion 135 may include a pin-socket connection (either the second die 130 or the first die 120 having pins and the other having corresponding sockets). The second connection portion 135 may include a second power transfer region and/or a second signal transfer region. The second die 130 may receive power from the first die 120 and/or the package substrate 110 through the second power transfer region. The second die 130 may transmit or receive a signal to or from the first die 120 and/or the package substrate 110 through the second signal transfer region.

In an example embodiment, the second dies 130 may be memory dies, which may be formed of a high bandwidth memory (HBM). The first die 120 may be a logic die. In an example embodiment, the stacked IC package 100 may secure HBM capacity as multiple HBMs are stacked on one logic die. The stacked IC package 100 may be applied to electronic equipment that requires high computing power, high functionality, and/or high efficiency, such as, for example, a supercomputer or a high-performance computing (HPC) system.

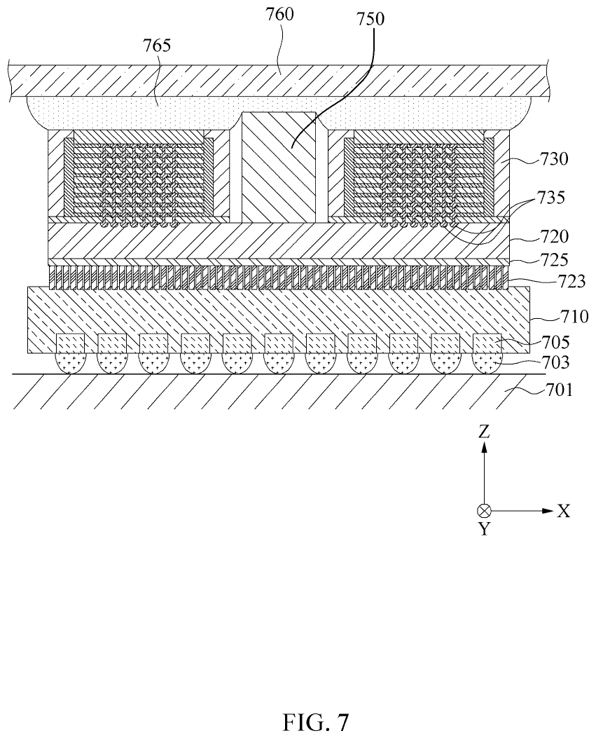

In an example embodiment, the stiffener 150 may be stacked on the first die 120. The stiffener 150 may be disposed between the second dies 130. The stiffener 150 may be formed of a rigid body such as stainless steel or aluminum, in which case the stiffener 150 may also function to transfer heat away from the first die 120 (e.g., to a thermal module as discussed with reference to FIG. 7). The stiffener 150 may be stacked on the first die 120 through an adhesive material such as epoxy or silicone.

In an example embodiment, the stiffener 150 may reinforce the rigidity of the first die 120. For example, warpage may occur on top of the first die 120 due to the second dies 130 stacked thereon. The stiffener 150 may be connected to the first die 120 to reinforce the rigidity of the first die 120, thereby reducing or preventing the warpage of the first die 120.

In an example embodiment, the stiffener 150 may provide mechanical rigidity to the stacked IC package 100. The stiffener 150 may reinforce the rigidity of the first die 120 disposed at the center of the stacked IC package 100, thereby assisting the first die 120 in supporting the plurality of second dies 130 and the package substrate 110.

The stiffener 150 may contribute to downsizing the stacked IC package 100 as it is stacked on the top surface of the first die 120. For example, when the stiffener 150 is stacked on the package substrate 110, the stiffener 150 may be arranged to surround (or partly surround) an outer perimeter surface of the first die 120, or an additional space (in addition to a space in which the first die 120 is disposed) may be required in the package substrate 110. Alternatively, in a case in which the stiffener 150 surrounds the package substrate 110, the stiffener 150 may be arranged to surround the package substrate 110. In an example embodiment, arranging the stiffener 150 on the first die 120 in the stacked IC package 100 may reduce the overall size of the stacked IC package 100, making the stacked IC package 100 downsized.

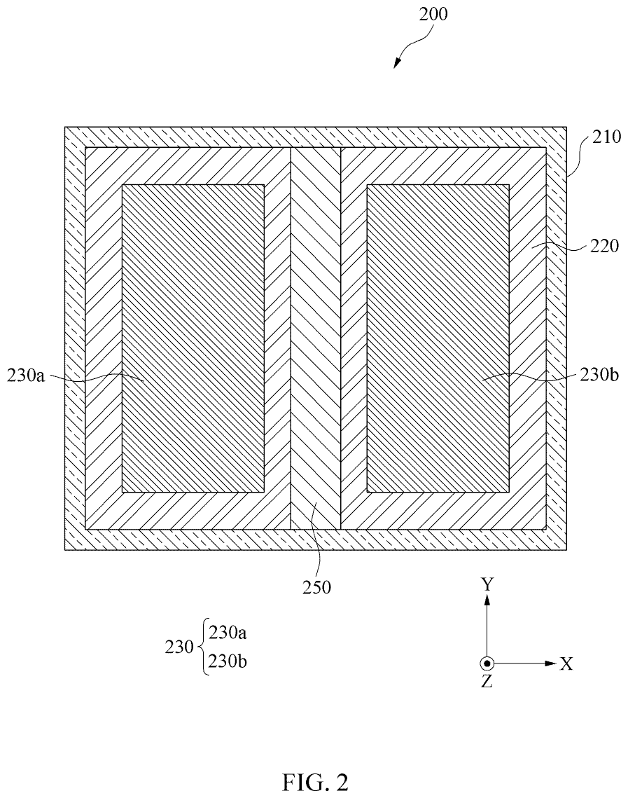

For example, when the stacked IC package 100 is of a substantially square structure as shown in FIGS. 2, 3, and 4, each side (length/width dimension) of the package substrate 110 may be 24 millimeters (mm), and the width of the stiffener 150 may be 1 mm.

However, the term “substantially” used herein indicates the same level of deviation as a tolerance or error used in a general manufacturing process. Alternatively, the term “substantially” used herein indicates a range including at least one of +/−0.1%, +/−0.5%, +/−1%, +/−3%, +/−5%, +/−7%, +/−10%, +/−15%, and +/−20%, based on the literal equivalent of 0.

In a case in which the stiffener 150 surrounds the outer perimeter surface of the package substrate 110 or the first die 120, the stacked IC package 100 may be formed to have the length of one side which is 28 mm or more, in further consideration of a bleeding length of an adhesive member for attaching the stiffener 150.

In an example embodiment, when the stiffener 150 is disposed on the first die 120, a space for disposing the stiffener 150 in the package substrate 110 or the stacked IC package 100 may not be required, and the stacked IC package 100 may therefore be formed to have the length of one side which is 24 mm (in the X or Y direction). Accordingly, in some embodiments, the length of the stacked IC package 100 may be reduced by more than 14%, and the area thereof may also be reduced by more than 26%.

In an example embodiment, the stiffener 150 may be formed as one integral body. The stiffener 150 may be formed of a single material. Compared to some other cases in which it is formed as a separable body or a discontinuous body and attached (e.g., by epoxy), the stiffener 150 formed as one continuous integral body may be effective in reinforcing the rigidity of the stacked IC package 100.

Hereinafter, various implementation examples of the stacked IC package 100 will be described according to one or more example embodiments, based on the foregoing description of the stacked IC package 100. However, the stacked IC package 100 of various example embodiments is not limited to the following structures and descriptions, and the structure, shape, type, and/or function of the stacked IC package 100 may be modified without limitation.

FIG. 2 is a plan view (overhead view) of a stacked IC package 200, according to one or more embodiments.

Referring to FIG. 2, the stacked IC package 200 (e.g., the stacked IC package 100 of FIG. 1) of an example embodiment may include at least some of a package substrate 210 (e.g., the package substrate 110 of FIG. 1) (the package substrate 210 may extend beyond the stacked IC package 200 and have other components mounted thereon (e.g., other stacked IC packages)), a first die 220 (e.g., the first die 120 of FIG. 1), second dies 230 (e.g., the second dies 130 of FIG. 1), and a stiffener 250 (e.g., the stiffener 150 of FIG. 1).

Hereinafter, what has been described above will not be repeated, with the understanding that some configurations and structures may be replaced, added, or omitted in describing the stacked IC package 200 without departing from a range that can be easily understood by those skilled in the art from the following description and the accompanying drawings. In addition, at least one of the configurations or features described above may be combined in the stacked IC package 200 unless clearly technically impossible.

In an example embodiment, the plurality of second dies 230 may include two second dies 230a and 230b that are spaced apart from each other. The two second dies 230a and 230b may be disposed on the first die 220 to be spaced apart in one direction (e.g., an X-axis direction).

In an example embodiment, the stiffener 250 may be formed as a linear structure that is arranged lengthwise between the two second dies 230a and 230b. The stiffener 250 of the linear structure may stabilize and support a top surface of the first die 220 and reduce or prevent the warpage of the stacked IC package 200.

For example, as shown by the top view of the stacked IC package 200 shown in FIG. 2 (viewed in a −Z direction), the stiffener 250 may be formed with a linear structure, akin to a beam or girder, that extends continuously from one end of the first die 220 (e.g., an end in a +Y direction) to an opposite end thereof (e.g., an end in a −Y direction).

In an example embodiment, the stiffener 250 may be formed in a partition structure that runs with the lengths of, and between, two neighboring second dies 230 among the second dies 230. In an example embodiment, the stiffener 250 may be formed in a partition space (for example, a linear partition space) between the two neighboring second dies 230. The stiffener 250 of the partition structure may be effective in reinforcing the rigidity of the stacked IC package 200. Alternatively, the stiffener 250 of the partition structure may partition between the second dies 230 and provide space efficiency to the stacked IC package 200.

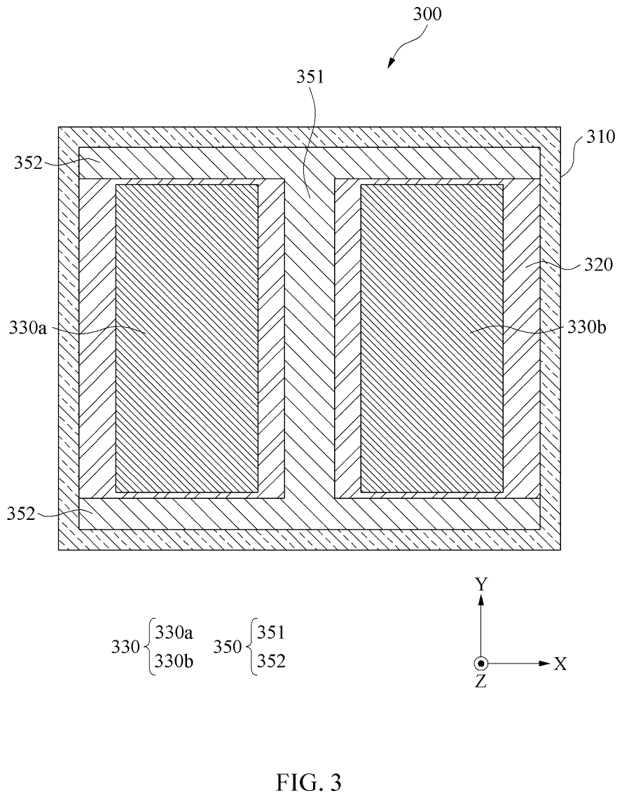

FIG. 3 is a schematic plan view of a stacked IC package 300, according to one or more example embodiments.

Referring to FIG. 3, the stacked IC package 300 (e.g., the stacked IC package 100 of FIG. 1) of an example embodiment may include at least some of a package substrate 310 (e.g., the package substrate 110 of FIG. 1), a first die 320 (e.g., the first die 120 of FIG. 1), second dies 330 (e.g., the plurality of second dies 130 of FIG. 1), and a stiffener 350 (e.g., the stiffener 150 of FIG. 1, albeit possibly of different form).

Hereinafter, what has been described above will not be repeated but omitted, and it is to be understood that some configurations and structures may be replaced, added, or omitted in describing the stacked IC package 300 without departing from a range that can be easily understood by those skilled in the art from the following description and the accompanying drawings. In addition, at least one of the configurations or features described above may be combined in the stacked IC package 300 unless clearly technically impossible.

In an example embodiment, the second dies 330 may include two second dies 330a and 330b that are spaced apart from each other. The two second dies 330a and 330b may be disposed on the first die 320 to be spaced apart in one direction (e.g., an X-axis direction).

In an example embodiment, the stiffener 350 may include a first region 351 and at least one second region 352. The first region 351 may be formed in a linear structure that extends between the two second dies 330a and 330b (e.g., an “H” shaped structure, viewed from above). For example, the first region 351 may be formed in a partition structure that extends between the two second dies 330a and 330b. The first region 351 of the stiffener 350 may stabilize and support a top surface of the first die 320 and reduce or prevent warpage of the stacked IC package 300.

In an example embodiment, the second region 352 may be opposite to one surface of the two second dies 330a and 330b facing an outer side of the stacked IC package 300. For example, as shown in FIG. 3, the stiffener 350 may include one second region 352 facing an a top side (e.g., a surface in a +Y direction) of the second dies 330a and 330b, and the other second region 352 facing a bottom side (e.g., a surface in a −Y direction) of the second dies 330a and 330b. Put another way, the stiffener 350 may be configured such that its vertical walls face each vertical side of the second dies 330a and 330b except for the side of each such die that faces away from both such dies (in FIG. 3, the left side of second die 330a and the right side of second die 330b).

In an example embodiment, the second region 352 may be formed as a linear structure that extends along an edge of the first die 320 (in some examples flush therewith). The second region 352 of the stiffener 350 may stabilize and support the top surface of the first die 320 and reduce or prevent warpage of the stacked IC package 300.

In an example embodiment, the first region 351 and the at least one second region 352 may be connected to each other (e.g., bonded or part of an integrated “H” shaped structure). The first region 351 and the at least one second region 352 may be integrally connected to form the stiffener 350 as one body. Compared to other cases in which the first region 351 and the at least one second region 352 are separable or discontinuous, the stiffener 350 formed as the one integral continuous body may be effective in reinforcing the rigidity of the stacked IC package 300.

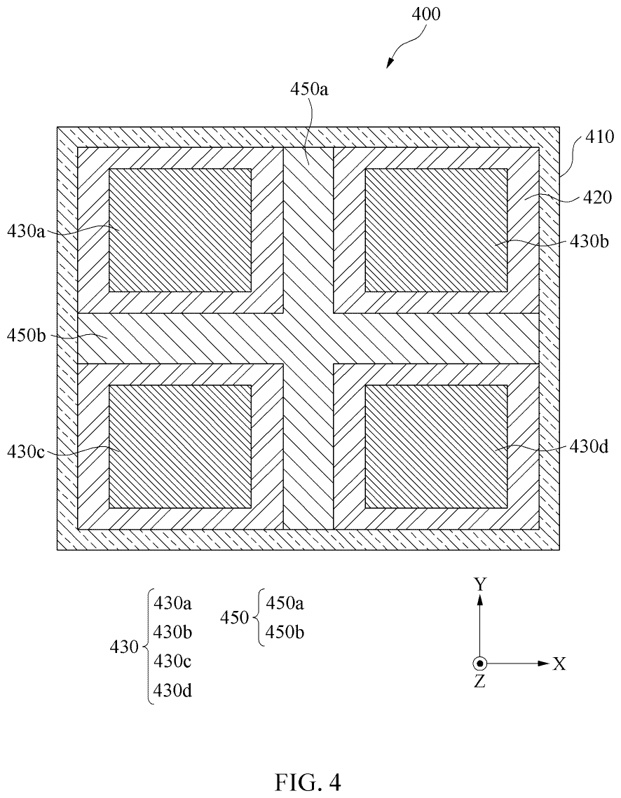

FIG. 4 is a plan view of a stacked IC package 400, according to one or more example embodiments.

Referring to FIG. 4, the stacked IC package 400 (e.g., the stacked IC package 100 of FIG. 1, albeit with possible structural variations) of an example embodiment may include at least some of a package substrate 410 (e.g., the package substrate 110 of FIG. 1), a first die 420 (e.g., the first die 120 of FIG. 1), second dies 430 (e.g., the plurality of second dies 130 of FIG. 1), and a stiffener 450 (e.g., the stiffener 150 of FIG. 1).

Hereinafter, what has been described above will not be repeated but omitted, and it is to be understood that some configurations and structures may be replaced, added, or omitted in describing the stacked IC package 400 without departing from a range that can be easily understood by those skilled in the art from the following description and the accompanying drawings. In addition, at least one of the configurations or features described above may be combined in the stacked IC package 400 unless clearly technically impossible.

In an example embodiment, the second dies 430 may be arranged in a matrix structure and spaced apart from each other (when viewed from above). For example, the plurality of second dies 430 may include four second dies 430a, 430b, 430c, and 430d arranged in a rectilinear pattern.

In an example embodiment, the four second dies 430a, 430b, 430c, and 430d may be arranged on the first die 420 to be spaced apart from each other in a column direction (e.g., a Y-axis direction, an up-down direction, or a vertical direction) and a row direction (e.g., an X-axis direction, a left-right direction, or a horizontal direction). For example, the two second dies 430a and 430b may be arranged in one row, and the other two second dies 430c and 430d may be arranged in another row. For example, the two second dies 430a and 430c may be arranged in one column, and the other two second dies 430b and 430d may be arranged in another column.

In an example embodiment, the stiffener 450 may be formed in a plurality of linear structures that extend across the four second dies 430a, 430b, 430c, and 430d. The stiffener 450 of the linear structures may stably support a top surface of the first die 420 and reduce or prevent the warpage of the stacked IC package 400. For example, the stiffener 450 may have a “+” shape.

In an example embodiment, the stiffener 450 may include a first extension region 450a and a second extension region 450b. The first extension region 450a may extend in the column direction between neighboring second dies 430 (e.g., between 430a and 430b or between 430c and 430d) that are adjacent in the row direction among the plurality of second dies 430. The second extension region 450b may extend in the row direction between neighboring second dies 430 (e.g., between 430a and 430c or between 430b and 430d) that are adjacent in the column direction among the plurality of second dies 430.

In an example embodiment, each of the first extension region 450a and the second extension region 450b may be formed in a linear structure that extends among the plurality of second dies 430. For example, the first extension region 450a may be formed in a partition structure that extends in the column direction, and the second extension region 450b may be formed in a partition structure that extends in the row direction. The first extension region 450a and the second extension region 450b of the stiffener 450 may stably support the top surface of the first die 420 and reduce or prevent the warpage of the stacked IC package 400.

In an example embodiment, the first extension region 450a and the second extension region 450b may be connected to each other. The first extension region 450a and the second extension region 450b may be integrally connected to form the stiffener 450 as one body. Compared to some other cases in which the first extension region 450a and the second extension region 450b are separable or discontinuous, the stiffener 450 formed as one integral continuous body may be effective in reinforcing the rigidity of the stacked IC package 400.

In another example, the stiffener 450 may be structured such that its vertical walls face each of (and only) the interior walls/surfaces of the second dies 430.

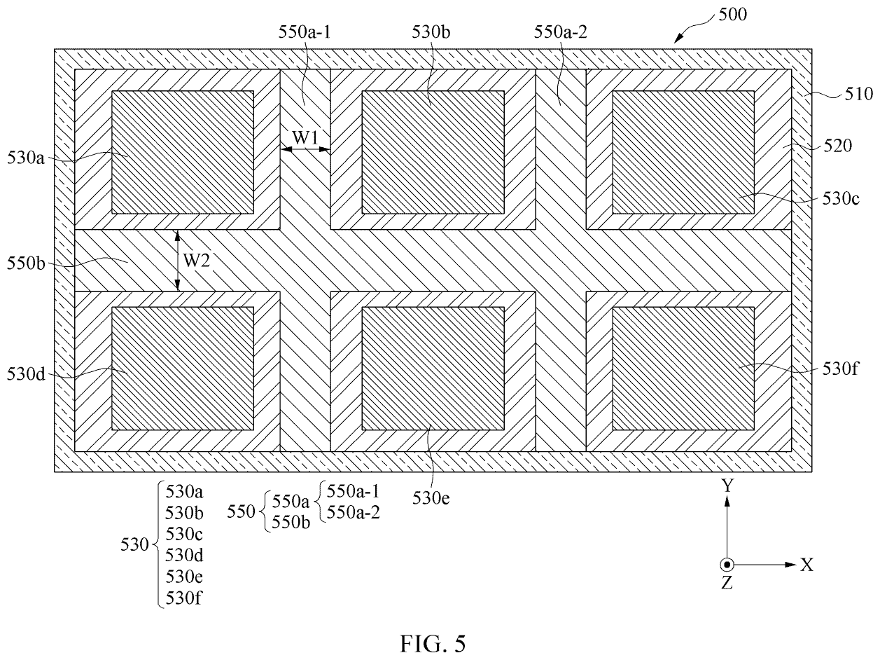

FIG. 5 is a plan view of a stacked IC package 500, according to one or more example embodiments.

Referring to FIG. 5, the stacked IC package 500 (e.g., the stacked IC package 100 of FIG. 1) of an example embodiment may include at least some of a package substrate 510 (e.g., the package substrate 110 of FIG. 1), a first die 520 (e.g., the first die 120 of FIG. 1), second dies 530 (e.g., the plurality of second dies 130 of FIG. 1), and a stiffener 550 (e.g., the stiffener 150 of FIG. 1, albeit with possible structural differences).

Hereinafter, what has been described above will not be repeated but omitted, and it is to be understood that some configurations and structures may be replaced, added, or omitted in describing the stacked IC package 500 without departing from a range that can be easily understood by those skilled in the art from the following description and the accompanying drawings. In addition, at least one of the configurations or features described above may be combined in the stacked IC package 500 unless clearly technically impossible.

In an example embodiment, the plurality of second dies 530 may be arranged in a matrix structure and spaced apart from each other. For example, the second dies 530 may include six second dies 530a, 530b, 530c, 530d, 530e, and 530f. However, examples are not limited thereto, and the plurality of second dies 530 may include two or more dies and arranged to be spaced apart from each other.

In an example embodiment, the six second dies 530a, 530b, 530c, 530d, 530e, and 530f may be arranged on the first die 520 to be spaced apart from each other in a column direction (e.g., a Y-axis direction, an up-down direction, or a vertical direction) and a row direction (e.g., an X-axis direction, a left-right direction, or a horizontal direction). For example, the three second dies 530a, 530b, and 530c may be arranged in one row, and the other three second dies 530d, 530e, and 530f may be arranged in another row. For example, the two second dies 530a and 530d may be arranged in one column, another two second dies 530b and 530e may be arranged in another column, and still another two dies 530c and 530f may be arranged in still another column. In short, second dies may be arranged in a rectilinear matrix with spacing between rows and columns of second dies, and the numbers of rows and columns is not limited.

In an example embodiment, the stiffener 550 may be formed in a plurality of linear structures that extends among the six second dies 530a, 530b, 530c, 530d, 530e, and 530f. The stiffener 550 formed in the plurality of linear structures may stably support a top surface of the first die 520 and reduce or prevent the warpage of the stacked IC package 500. In other words, the stiffener 550 may have a waffle-like structure that occupies the spaces between the columns and rows of second dies.

In an example embodiment, the stiffener 550 may include a first extension region 550a and a second extension region 550b. The first extension region 550a may extend in a column direction between neighboring second dies 530 (e.g., between 530a and 530b, between 530b and 530c, between 530d and 530e, or between 530e and 530f) that are adjacent in a row direction among the plurality of second dies 530. The second extension region 550b may extend in a row direction between neighboring second dies 530 (e.g., between 530a and 530d, between 530b and 530e, or between 530c and 530f) that are adjacent in a column direction among the plurality of second dies 530.

In an example embodiment, the stiffener 550 may include multiple regions which may be the first extension region 550a or the second extension region 550b. For example, as shown in FIG. 5, the stiffener 550 may include first extension regions 550a.

In this example, the plurality of first extension regions 550a may include two first extension regions 550a-1 and 550a-2. The two first extension regions 550a-1 and 550a-2 may include a first column extension region 550a-1 and a second column extension region 550a-2. The first column extension region 550a-1 and the second column extension region 550a-2 may be arranged to be spaced apart from each other in the row direction with at least one second die (e.g., 530b and 530e) disposed therebetween.

However, examples are not limited thereto, and the stiffener 550 may include a plurality of at least one of the first extension region 550a and the second extension region 550b based on an arrangement structure of the plurality of second dies 530. The stiffener 550 may extend while partitioning each of the plurality of second dies 530.

In an example embodiment, each of the first extension region 550a and the second extension region 550b may be formed in a rectilinear structure that extends among the plurality of second dies 530 (e.g., forming a hash-like structure “#”). For example, the first extension region 550a may be formed in a partition structure that extends in the column direction, and the second extension region 550b may be formed in a partition structure that extends in the row direction. The first extension region 550a and the second extension region 550b of the stiffener 550 may stably support the top surface of the first die 520 and reduce or prevent the warpage of the stacked IC package 500.

In an example embodiment, the first extension region 550a and the second extension region 550b may be connected to each other. The first extension region 550a and the second extension region 550b may be integrally connected to form the stiffener 550 as one body. Compared to some other cases in which the first extension region 550a and the second extension region 550b are separable or discontinuous, the stiffener 550 formed as one integral continuous body may be effective in reinforcing the rigidity of the stacked IC package 500.

In an example embodiment, the first die 520 may be different in length in a column direction and in a row direction. For example, as shown in FIG. 5, the length of the first die 520 in the row direction may be longer than the length in the column direction.

In an example embodiment, the stiffener 550 may be formed to have a width W1 in the row direction of the first extension region 550a and a width W2 in the column direction of the second extension region 550b, in which W1 and W2 are different. For example, the width W2 of the second extension region 550b in the column direction may be greater than the width W1 of the first extension region 550a in the row direction.

In an example embodiment, when the length of the first die 520 in the row direction is longer, the stacked IC package 500 may have a greater strength of being warped or have a greater probability of being warped in the row direction. In this case, forming the stiffener 550 to have a greater width (e.g., W2) of the second extension region 550b extending in the row direction may reduce or prevent the warpage of the stacked IC package 500 in response to the length of the first die 520. In some examples, whichever dimension is greater (e.g., X dimension or Y dimension) will have the greater width of W1 or W2, as the case may be.

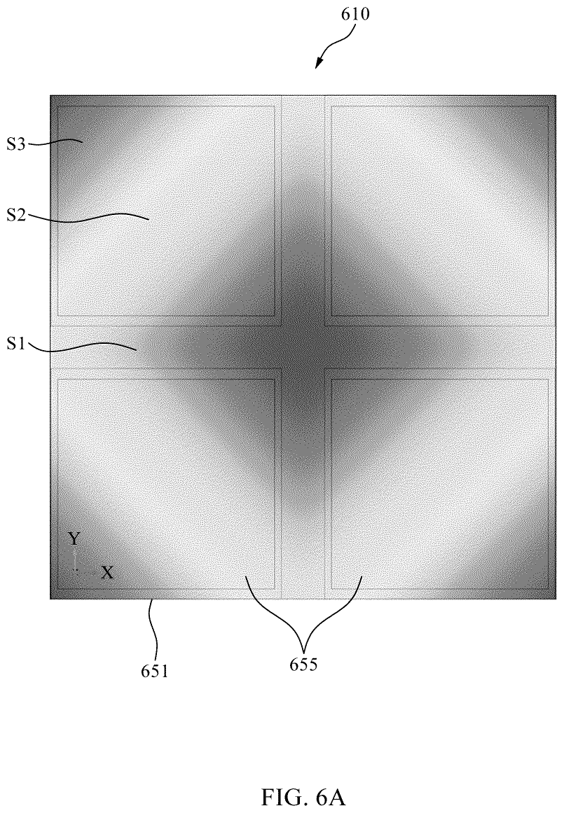

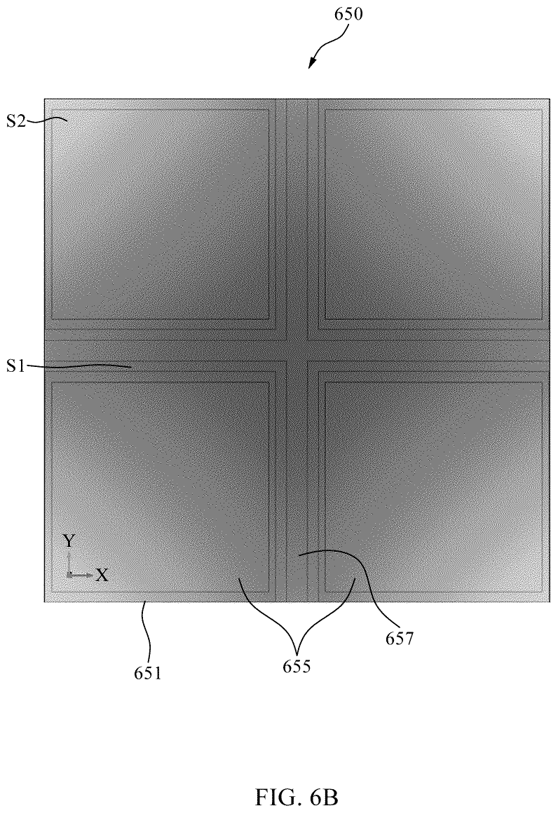

FIG. 6A is an overhead view showing the warpage of a stacked IC package 610 without a stiffener, according to one or more example embodiments, and FIG. 6B is an overhead view showing warpage of a stacked IC package 650 with a stiffener, according to one or more example embodiments.

Referring to FIGS. 6A and 6B, the stacked IC package 650 may include a stiffener 657 to have an increased resistance to warpage, and the stiffener 657 may reduce or prevent the warpage.

Hereinafter, what has been described above will not be repeated but omitted, and it is to be understood that some configurations and structures may be replaced, added, or omitted in describing the stacked IC package 610 or 650 without departing from a range that can be easily understood by those skilled in the art from the following description and the accompanying drawings. In addition, at least one of the configurations or features described above may be combined in the stacked IC package 610 or 650 unless clearly technically impossible.

In addition, substantially the same or similar descriptions of at least one of the stacked IC packages (e.g., 100, 200, 300, 400, and 500) described above may be applied to the following description of the stacked IC packages 610 and 650 of FIGS. 6A and 6B, and substantially the same or similar descriptions of the stiffeners (e.g., 150, 250, 350, 450, and 550) described above may be applied to the following description of the stiffener 657 of FIG. 6B.

In the examples of FIGS. 6A and 6B, the length of one side of the stacked IC packages 610 and 650 may be 24 mm. A first space S1 may be a region in which no warpage of the stacked IC packages 610 and 650 occurs or in which the warpage ranges from 0 to 100 μm. A second space S2 may be a region in which the warpage of the stacked IC packages 610 and 650 ranges from 100 to 300 μm. A third space S3 may be a region in which the warpage of the stacked IC packages 610 and 650 ranges from 300 to 500 μm. The aforementioned dimension values are non-limiting examples.

Specifically, FIG. 6A shows warpage of the stacked IC package 610, during its use, where second dies 655 are stacked on a first die 651 and the stiffener 657 is not included.

Specifically, FIG. 6B shows the warpage of the stacked IC package 650, during its use, where the second dies 655 and the stiffener 657 are stacked on the first die 651.

Spaces S1, S2, and S3 refer to regions of the stacked IC package 610 or 650 (not structural elements per se), and are included for discussing warpage degree and pattern. In an example embodiment, compared to the stacked IC package 610 without the stiffener 657, the stacked IC package 650 including the stiffener 657 may have a wider area of warpage of the first space S1. In an example embodiment, compared to the stacked IC package 610 without the stiffener 657, the stacked IC package 650 including the stiffener 657 may have the second space S2 that moved to the corners of the stacked IC package 650, and the third space S3 is practically dissipated. In an example embodiment, the stacked IC package 650 including the stiffener 657 may substantially reduce warpage to within 100 μm, and the stiffener 657 may provide durability and stability to the stacked IC package 650.

FIG. 7 is a cross-sectional view of a stacked IC package 700 according to one or more example embodiments.

Referring to FIG. 7, according to an example embodiment, the stacked IC package 700 (e.g., the stacked IC package 100 of FIG. 1 or others) may further include a thermal module 760 and a thermal interface material (TIM) 765.

Hereinafter, what has been described above will not be repeated but omitted, and it is to be understood that some configurations and structures may be replaced, added, or omitted in describing the stacked IC package 700 without departing from a range that can be easily understood by those skilled in the art from the following description and the accompanying drawings. In addition, at least one of the configurations or features described above may be combined in the stacked IC package 700 unless clearly technically impossible.

In an example embodiment, a package substrate 710 may form a base of the stacked IC package 700. The package substrate 710 may provide a physical mounting space for the components of the stacked IC package 700 to be mounted therein.

In an example embodiment, dies (e.g., 720 and 730) may be stacked on the package substrate 710. For example, a first die 720 and a second die 730 may be stacked on one surface (e.g., a surface in a +Z direction or a top surface) of the package substrate 710.

The stacked IC package 700 may be disposed on an external substrate 701. A substrate connection portion 705 may be provided on another surface of the package substrate 710 (e.g., a surface in a −Z direction or bottom surface). The substrate connection portion 705 may connect the stacked IC package 700 to the external substrate 701. A coupling member 703 may be applied onto the substrate connection portion 705. The coupling member 703 may be a shouldering member or a conductive paste.

In an example embodiment, the package substrate 710 may transmit electrical signals from the plurality of dies 720 and 730 to the external substrate 701 through the substrate connection portion 705. Alternatively, the package substrate 710 may transmit power from the external substrate 701 to the plurality of dies 720 and 730 through the substrate connection portion 705.

In an example embodiment, a first die 720 may be stacked on the package substrate 710. For example, the first die 720 may be stacked on one surface (e.g., the surface in the +Z direction) of the package substrate 710. The first die 720 may be either a logic die or a memory die. However, this is provided only as an example, and the type of the first die 720 is not limited thereto. The first die 720 may provide a space for mounting second dies 730 and a stiffener 750.

In an example embodiment, the first die 720 may include a first connection portion 725. The first connection portion 725 may electrically connect the first die 720 and the package substrate 710. A connecting member 723 may be provided between the first connection portion 725 and the package substrate 710. The connecting member 723 may be a shouldering member, a cable, a conductive structure, a pin, a conductive paste, or the like.

In an example embodiment, the first connection portion 725 may include at least a portion of a first power transfer region and a first signal transfer region. The first die 720 may receive power from the package substrate 710 through the first power transfer region. The first die 720 may transmit or receive a signal to or from the package substrate 710 through the first signal transfer region.

In an example embodiment, the second dies 730 may be stacked on the first die 720. For example, the second dies 730 may each be stacked on a top surface (e.g., a surface in the +Z direction) of the first die 720. The second dies 730 may be either logic dies or memory dies. For example, the first die 720 may be a logic die, and the second dies 730 may be memory dies. For example, the first die 720 may be a memory die, and the second dies 730 may be logic dies. For example, the first die 720 may be a logic die, and the second dies 730 may be logic dies. However, these are provided only as examples, and the types of the first die 720 and the plurality of second dies 730 are not limited thereto.

In an example embodiment, the second dies 730 may each include a second connection portion 735. Each second connection portion 735 may electrically connect the corresponding second die 730 and the first die 720. The second connection portion 735 may include a second power transfer region and/or a second signal transfer region. The second die 730 may receive power from the first die 720 and/or the package substrate 710 through the second power transfer region. The second die 730 may transmit or receive signals to or from the first die 720 and/or the package substrate 710 through the second signal transfer region.

In an example embodiment, the second dies 730 may be memory dies, and the memory dies may be formed with HBMs. The first die 720 may be a logic die. In an example embodiment, the stacked IC package 700 may secure HBM capacity as HBMs are stacked on one logic die. The stacked IC package 700 may be applied to electronic equipment that requires high computing power, high functionality, and/or high efficiency, such as, a supercomputer or an HPC system.

In an example embodiment, the stiffener 750 may be stacked on the first die 720. The stiffener 750 may be disposed between the second dies 730. The stiffener 750 may be formed of a rigid body such as stainless steel or aluminum. The stiffener 750 may be stacked on the first die 720 with an adhesive material such as epoxy or silicone.

In an example embodiment, the stiffener 750 may reinforce the rigidity of the first die 720. For example, there may be warpage (or warping forces) in the first die 720 due to the second dies 730 stacked thereon. The stiffener 750 may be coupled to the first die 720 to reinforce the rigidity of the first die 720, thereby reducing or preventing warpage of the first die 720.

In an example embodiment, the stiffener 750 may provide mechanical rigidity to stacked IC package 700. The stiffener 750 may reinforce the rigidity of the first die 720 at the center of the stacked IC package 700, thereby assisting the first die 720 in supporting the second dies 730 and the package substrate 710.

In an example embodiment, the thermal module 760 may be disposed on the second dies 730 and the stiffener 750. The thermal module 760 may include a cooling fan or a cooling passage. The thermal module 760 may cool the stacked IC package 700 and emit the heat generated from the stacked IC package 700 to the outside. The thermal module 760 may be any form of heat dissipater, e.g., a heat sink, a mechanical dissipater, or the like.

In an example embodiment, the TIM 765 may be applied between the thermal module 760 and at least one of the second dies 730 and the stiffener 750. The TIM 765 may be formed of a material with a desirable thermal conductivity. The TIM 765 may support the second dies 730, the stiffener 750, and the thermal module 760.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure should be defined by the claims and their equivalents, and in addition to the above disclosure, all variations within the scope of the claims and their equivalents are to be construed as being included in the disclosure.

What is claimed is:

1. A stacked integrated circuit (IC) package, comprising:
a package substrate;
a first die stacked on the package substrate;
second dies each stacked on the first die and spaced apart from each other on the first die; and
a stiffener stacked on the first die and arranged between the second dies.

2. The stacked IC package of claim 1, wherein the second dies comprise two neighboring second dies, and wherein the stiffener is formed lengthwise in a partition space between the two neighboring second dies.

3. The stacked IC package of claim 1, wherein the stiffener is formed as one integral body.

4. The stacked IC package of claim 1, wherein the stiffener is formed of stainless steel or aluminum.

5. The stacked IC package of claim 1, wherein the second dies are memory dies and the first die is a processor die.

6. The stacked IC package of claim 1, wherein the stiffener comprises a linear structure arranged in a corresponding linear space between two second dies without contacting the two second dies.

7. The stacked IC package of claim 1, wherein the stiffener comprises:
a first linear portion disposed between two second dies; and
a second linear portion having a first side and a second side opposite the first side, wherein the first side faces the two second dies, and wherein the second side faces outward from the stacked IC package.

8. The stacked IC package of claim 7, wherein the first linear portion and the second linear portion perpendicular to each other and are connected to, or integrated with, each other to form the stiffener as one body.

9. The stacked IC package of claim 1, wherein the second dies comprise four second dies and the four second dies are arranged in a matrix pattern and spaced apart from each other.

10. The stacked IC package of claim 9, wherein the stiffener comprises:
a first linear portion arranged between neighboring second dies in a first direction among the four second dies; and
a second linear portion perpendicular to the first linear portion and arranged between neighboring second dies in a second direction different from the first direction among the four second dies.

11. The stacked IC package of claim 10, wherein the first linear portion and the second linear portion are connected to, or integrated with, each other to form the stiffener as one body.

12. The stacked IC package of claim 10, wherein the stiffener further comprises a third linear portion parallel to the first linear portion and perpendicular to the second linear portion.

13. The stacked IC package of claim 10, wherein the first die is wider in a dimension parallel to the first linear portion than in a dimension parallel to the second linear portion,
wherein the first linear portion is thicker than the second linear portion.

14. The stacked IC package of claim 1, further comprising:
a thermal module disposed on the second dies and the stiffener.

15. The stacked IC package of claim 14, further comprising:
a thermal interface material (TIM) applied between the thermal module and at least one of the second dies and the stiffener.

16. A stacked integrated circuit (IC) package, comprising:
a package substrate;
a logic die stacked on the package substrate;
memory dies each stacked on the logic die and spaced apart from each other on the logic die; and
a stiffener stacked on the logic die and arranged between the memory dies.

17. The stacked IC package of claim 16, wherein each of the memory dies is formed with a high bandwidth memory (HBM) and each of the memory dies has a respective electrical connection with the logic die.

18. The stacked IC package of claim 16, wherein the stiffener has linear shape and is formed in a linear partition space between two neighboring memory dies.

19. The stacked IC package of claim 16, wherein the stiffener is formed as one integral body.

20. The stacked IC package of claim 16, wherein the stiffener, from a perspective above the stacked IC package, comprises a “+” shape or an “H” shape.
